(19) United States
(12) Patent Application Publication
(10) Pub. No.: US 2023/0378280 A1
(43) Pub. Date: Nov. 23, 2023

(54) PREPARATION METHOD OF DOUBLE-T-SHAPED GATE BASED ON DOUBLE-LAYER PASSIVATION ACCURATE ETCHING

(71) Applicant: SOUTH CHINA UNIVERSITY OF TECHNOLOGY, Guangzhou (CN)

(72) Inventors: Wenliang WANG, Guangzhou (CN); Shanjie LI, Guangzhou (CN); Guoqiang LI, Guangzhou (CN); Zhiheng XING, Guangzhou (CN); Nengtao WU, Guangzhou (CN)

(73) Assignee: SOUTH CHINA UNIVERSITY OF TECHNOLOGY, Guangzhou (CN)

(21) Appl. No.: 18/030,516

(22) PCT Filed: Jul. 28, 2022
(86) PCT No.: PCT/CN2022/108634

§ 371 Date: Apr. 6, 2023

(30) Foreign Application Priority Data
Jul. 30, 2021 (CN) 202110871188.7

(51) Int. Cl. H01L 29/40; H01L 23/31; H01L 23/29; H01L 29/423; H01L 21/56

(52) U.S. Cl. CPC H01L 29/401; H01L 23/3171; H01L 23/291; H01L 29/42376; H01L 21/56; H01L 29/66462

(57) ABSTRACT

A preparation method of a double-T-shaped gate based on double-layer passivation accurate etching includes: sequentially growing two passivation layers on an epitaxial structure, where the two passivation layers include a bottom passivation layer and a top passivation layer; performing a first exposure on the top passivation layer and etching the top passivation layer and the bottom passivation layer in a first exposure region from top to bottom to form a gate root region; performing a second exposure on the top passivation layer and etching the top passivation layer in a second exposure region to form a lower gate cap region; and performing a third exposure on the top passivation layer to form a top gate cap exposure region and performing metal evaporation and removing a photoresist to form a double-T-shaped gate structure in the two passivation layers.

### TECHNICAL FIELD

The present disclosure relates to the technical field of high-frequency high-electron-mobility field effect transistors, particularly to a preparation method of a double-T-shaped gate based on double-layer passivation accurate etching.

### BACKGROUND

High-electron-mobility transistors represented by AlGaN/GaN and GaAs/AlGaAs heterojunction structures feature high frequency, high speed, high voltage resistance, and high power and are widely used in the radio frequency microwave field. The gate preparation process greatly affects the high-frequency performance of the device. To obtain high-gain, low-noise, and high-speed radio frequency devices, the key requirement is to reduce the gate length. However, the reduction of the gate length increases the gate resistance, affecting the high-frequency performance of the device. At present, the T-shaped gate process has been recognized as the mainstream technology for the preparation of high-frequency devices. The short gate root ensures the high-frequency performance of the device, while the long gate cap reduces the gate resistance. Therefore, it is of great importance to study and optimize the preparation process of the T-shaped gate.

At present, the mainstream method of preparing the T-shaped gate is an electron beam lithography tri-layer photoresist process. This process is extremely tedious since it requires three times of exposure and development. Moreover, to prevent mixing between photoresist layers, multiple baking and development processes are needed to obtain a T-shaped gate pattern. With an increasingly high requirement on the reliability of radio frequency devices, the devices are not only required to have high frequency and high power but also required to have a weak current collapse effect. Therefore, there is an urgent need to improve the T-shaped gate process. A double-T-shaped gate is obtained by adding a gate cap on top of the T-shaped gate. The added gate cap not only reduces the gate resistance but also disperses the electric field in the gate-drain region, thereby increasing the device breakdown voltage and suppressing the virtual gate effect. However, the double-T gate process is more tedious and more difficult to control. Additionally, it is difficult to control the thickness of the gate root metal and the gate cap metal. There is an urgent need to design a preparation method to simplify the double-T-shaped gate process and improve the device's reliability.

### SUMMARY

To overcome the disadvantages and shortcomings of the prior art, the present disclosure provides a preparation method of a double-T-shaped gate based on double-layer passivation accurate etching.

This method implements the preparation of a double-T-shaped gate by accurately etching two passivation layers with a high selectivity ratio. The preparation process can reduce the gate resistance and passivate the radio frequency device, which increases the breakdown voltage while reducing the virtual gate effect and avoiding current collapse, thereby improving the device's reliability.

The present disclosure adopts the following technical solutions:

A preparation method of a double-T-shaped gate based on double-layer passivation accurate etching is provided.

A double-T-shaped gate includes a gate root, a lower gate cap, and a top gate cap from bottom to top. The bottom of the gate root is in contact with an epitaxial structure, and the sidewall of the gate root is in contact with the bottom passivation layer. The bottom of the lower gate cap is in contact with the upper surface of the bottom passivation layer, and the sidewall of the lower gate cap is in contact with the top passivation layer. The bottom of the top gate cap is in contact with the upper surface of the top passivation layer, and the sidewall of the top gate cap is in contact with air.

The preparation method specifically includes:
sequentially growing two passivation layers on an epitaxial structure, where the two passivation layers include a bottom passivation layer and a top passivation layer;
performing a first exposure on the top passivation layer and etching the top passivation layer and the bottom passivation layer in a first exposure region from top to bottom to form a gate root region, where a dry etching gas cannot etch the epitaxial structure, thus protecting the integrity of the epitaxial structure;
performing a second exposure on the top passivation layer and wet-etching the top passivation layer in a second exposure region to form a lower gate cap region; and
performing a third exposure on the top passivation layer to form a top gate cap exposure region and performing metal evaporation and removing a photoresist to form a double-T-shaped gate structure in the two passivation layers.

Further, the preparation method specifically includes the following steps:
S1: growing the epitaxial structure on an epitaxial substrate and growing the two passivation layers on the epitaxial structure;
S2: coating the photoresist on the top passivation layer and performing the first exposure to expose the gate root region after development;
S3: performing dry etching on the gate root region, where an etching depth is the thickness of the two passivation layers, and then removing the photoresist;
S4: spin-coating the photoresist again and performing the second exposure on the top passivation layer to expose the lower gate cap region after development;
S5: performing accurate wet etching on the lower gate cap region, where a buffered oxide etch (BOE) solution can hardly etch the bottom passivation layer to ensure that an etching depth is the thickness of the top passivation layer, and then removing the photoresist;
S6: spin-coating the photoresist again and performing the third exposure on the top passivation layer to expose the top gate cap region;
S7: performing the metal evaporation on the epitaxial wafer and then removing the photoresist to complete the preparation of the double-T-shaped gate structure; and
S8: selecting an annealing atmosphere and an annealing temperature according to an electrode contact property to complete the preparation of the double-T-shaped gate.

Further, the width of the top gate cap is greater than the width of the lower gate cap, and the width of the lower gate cap is greater than the width of the gate root.

Further, the top passivation layer is SiO₂, the bottom passivation layer is SiN, and the two passivation layers are grown using plasma-enhanced chemical vapor deposition (PECVD), low-pressure chemical vapor deposition (LPCVD), and atomic layer deposition (ALD). This method does not require particular thicknesses of the top passivation layer and the bottom passivation layer and maximizes the degree of freedom of the device structure design.

Further, the dry etching in S3 is plasma etching, and the etching atmosphere is a fluorinated gas.

Further, the width of the top gate cap exposure region is greater than the width of the lower gate cap exposure region, and the width of the lower gate cap exposure region is greater than the width of the gate root exposure region.

Further, the etching solution used in the wet etching in S5 is the BOE solution, which can hardly etch the SiN layer, thereby ensuring the accuracy of the gate root width.

Further, metal evaporation is implemented by physical vapor deposition with a metal lift-off process.

Further, the two passivation layers are grown using PECVD.

The present disclosure has the following beneficial effects:
(1) The present disclosure introduces passivation layers to prepare a double-T-shaped gate structure, which suppresses the current collapse effect and virtual gate effect of the device.
(2) In the present disclosure, a double-T-shaped gate structure is produced by performing etching and evaporation on the two passivation layers to simplify the preparation process of the double-T-shaped gate, thereby avoiding mixing between multiple photoresist layers and improving the preparation accuracy of the double-T-shaped gate.
(3) In the present disclosure, based on a developed etching process, it is unnecessary to etch the barrier layer, and SiN is skillfully used as a bottom passivation layer. During the etching of the gate root region, the fluorinated gas cannot destroy an AlGaN barrier layer. During the etching of the lower gate cap region, the BOE solution cannot etch the bottom passivation layer SiN, which ensures the etching precision, thereby further improving the preparation accuracy of the double-T-shaped gate.
(4) This method has high selectivity. Different etching methods can be used according to the different characteristics of SiO₂ and SiN. Controlling the thickness of the gate root means controlling the thickness of SiN, and controlling the thickness of the bottom gate cap means controlling the thickness of SiO₂.

### BRIEF DESCRIPTION OF THE DRAWINGS

FIG. 1 is a structural diagram of a double-T-shaped gate according to the present disclosure;

FIG. 2 is a schematic structural diagram of a double-T-shaped gate AlGaN/GaN high-electron-mobility transistor (HEMT) device according to Embodiment 1 of the present disclosure;

FIG. 3 is a diagram of a transfer characteristic curve of the double-T-shaped gate prepared in Embodiment 1 of the present disclosure; and

FIG. 4 is a schematic structural diagram of an output characteristic curve of the double-T-shaped gate prepared in Embodiment 1 of the present disclosure.

### DETAILED DESCRIPTION OF THE EMBODIMENTS

The present disclosure is further described below by referring to the embodiments and accompanying drawings, but the implementations of the present disclosure are not limited thereto.

### Embodiment 1

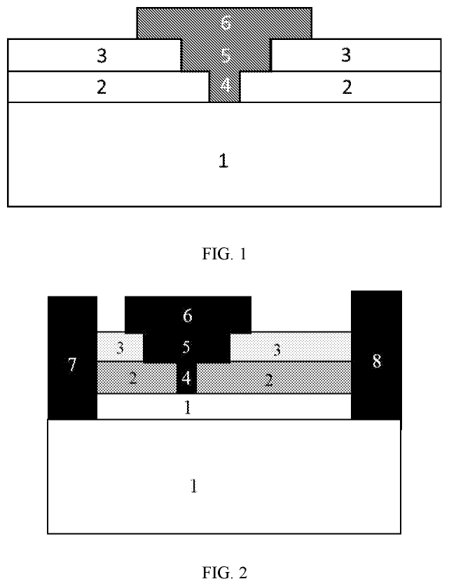

This embodiment provides a preparation method of a double-T-shaped gate based on double-layer passivation accurate etching and specifically provides a method for preparing a double-T-shaped gate AlGaN/GaN HEMT device based on double-layer passivation accurate etching. As shown in FIG. 2, the method is specified as follows:
(1) An AlGaN/GaN HEMT epitaxial wafer is coated with a photoresist for lithography and etching, and marks are made.
(2) The marks in step (1) are aligned, lithography is conducted, and then mesa isolation is conducted on the epitaxial wafer through etching.
(3) Source metal ohmic electrode 7 and drain metal ohmic electrode 8 are formed through lithography, followed by evaporation, lift-off, and annealing, where structures of the electrodes are shown in FIG. 2.
(4) Bottom passivation layer 2 made of SiN is grown by using a PECVD device, and then top passivation layer 3 made of SiO₂ is grown.
(5) The SiO₂ top passivation layer is coated with a photoresist, followed by lithography, development, dry etching, and other steps to form a gate root region.
(6) The SiO₂ top passivation layer is coated with the photoresist, followed by second lithography, development, and wet etching to form a lower gate cap region.
(7) The SiO₂ top passivation layer is coated with the photoresist, followed by third lithography, evaporation, and metal lift-off to form a top gate cap region and a gate metal electrode.
(8) The epitaxial wafer is taken out, and the photoresist on the epitaxial wafer is removed by using acetone.
(9) Lithography and evaporation are conducted to form a gate/source/drain metal electrode PAD.

The structure of the prepared product is shown in FIG. 1. Specifically, the double-T-shaped gate includes gate root 4, lower gate cap 5, and top gate cap 6 from bottom to top. The bottom of the gate root is in contact with epitaxial structure 1, and the sidewall of the gate root is in contact with the bottom passivation layer 2. The bottom of the lower gate cap is in contact with the upper surface of the bottom passivation layer, and the sidewall of the lower gate cap is in contact with the top passivation layer 3. The bottom of the top gate cap is in contact with the upper surface of the top passivation layer, and the sidewall of the top gate cap is in contact with air. The lower gate cap and the gate root are both in contact with the passivation layer, which can prevent the gate from falling over.

Preferably, the etching in step (1) and step (2) is performed by inductively coupled plasma (ICP) etching with an etching gas of a mixture of Cl₂ and BCl₃, a pressure of 5 mTorr, an upper radio frequency power of 300 W, a lower radio frequency power of 50 W, and an etching time of 150 s and an etching time of 80 s, respectively.

Preferably, the source and drain metal electrodes in step (3) are made of an alloy of Ti, Al, Ni, and Au.

Preferably, the annealing in step (3) is performed in an atmosphere of N₂ with an annealing temperature of 850° C., a temperature holding time of 30 s, and a heating rate of 15° C./s.

Preferably, the double passivation layers in step (4) are grown using PECVD, where the thicknesses of SiO₂ and SiN are 50 nm and 200 nm, respectively.

Preferably, the gate root region in step (5) has a length of 100 nm.

Preferably, the dry etching in step (5) uses a gas of SF₆ with a pressure of 5 mTorr, an upper radio frequency power of 300 W, a lower radio frequency power of 50 W, and an etching rate of 1 nm/s.

Preferably, the wet etching in step (6) uses a BOE solution.

Preferably, the lower gate cap region in step (6) has a length of 300 nm.

Preferably, the top gate cap region in step (7) has a length of 500 nm.

Preferably, the gate metal electrode in step (7) is composed of two metals: Ni and Au.

Preferably, the gate/source/drain metal electrode in step (9) is composed of two metals: Ni and Au.

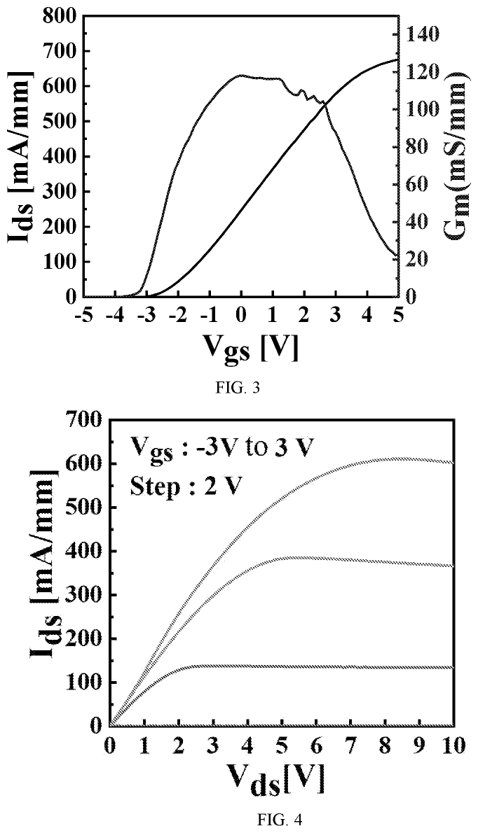

The transfer characteristic curve and the output characteristic curve of the double-T-shaped gate AlGaN/GaN HEMT prepared in Embodiment 1 are shown in FIG. 3 and FIG. 4, where the obtained device has a threshold voltage of −2.5 V and a maximum transconductance of 165 mS/mm. When the gate voltage is 3 V, an outputted saturated current density is 600 mA/mm, and the power added efficiency (PAE) of the device is 27% at the frequency of 35 GHz, showing excellent radio frequency performance.

### Embodiment 2

Embodiment 2 provides a preparation method of a double-T-shaped gate based on double-layer passivation accurate etching, which is specified as follows:
(1) A AlGaN/GaN HEMT epitaxial wafer is coated with a photoresist for lithography and etching, and marks are made.
(2) The marks in step (1) are aligned, lithography is conducted, and then mesa isolation is conducted on an epitaxial wafer through etching.
(3) A source metal ohmic electrode and a drain metal ohmic electrode are formed through lithography, followed by evaporation, lift-off, and annealing, where structures of the electrodes are shown in FIG. 1.
(4) The bottom passivation layer made of SiN is grown by using a PECVD device, and then a top passivation layer made of SiO₂ is grown.
(5) The SiO₂ top passivation layer is coated with a photoresist, followed by lithography, development, dry etching, and other steps on the passivation layer to form a gate root region.
(6) The SiO₂ top passivation layer is coated with the photoresist, followed by second lithography, development, and wet etching on the passivation layer to form a lower gate cap region.
(7) The SiO₂ top passivation layer is coated with the photoresist, followed by third lithography, evaporation, and metal lift-off to form a top gate cap region and a gate metal electrode.
(8) The epitaxial wafer is taken out, and the photoresist on the epitaxial wafer is removed by using acetone.
(9) Lithography and evaporation are conducted to form a gate/source/drain metal electrode PAD.

Preferably, the etching in step (1) and step (2) is ICP etching with an etching gas of a mixture of Cl₂ and BCl₃, a pressure of 5 mTorr, an upper radio frequency power of 300 W, a lower radio frequency power of 50 W, and an etching time of 150 s and an etching time of 80 s respectively.

Preferably, the source and drain metal electrodes in step (3) are made of an alloy of Ti, Al, Ni, and Au.

Preferably, the annealing in step (3) is performed in an atmosphere of N₂, with an annealing temperature of 850° C., a temperature holding time of 30 s, and a heating rate of 15° C./s.

Preferably, the passivation layers in step (4) are grown using LPCVD, where thicknesses of SiO₂ and SiN are 200 nm and 50 nm respectively.

Preferably, the dry etching in step (5) uses a gas of SF₆, with a pressure of 5 mTorr, an upper radio frequency power of 300 W, a lower radio frequency power of 50 W, and an etching rate of 1 nm/s.

Preferably, the wet etching in step (6) uses a BOE solution.

Preferably, the gate root region in step (5) has a length of 200 nm.

Preferably, the lower gate cap region in step (6) has a length of 400 nm.

Preferably, the top gate cap region in step (7) has a length of 600 nm.

Preferably, the gate metal electrode in step (7) is composed of two metals: Ni and Au.

Preferably, the gate/source/drain metal electrode in step (9) is composed of two metals: Ni and Au.

The transfer characteristic curve and the output characteristic curve of the double-T-shaped gate AlGaN/GaN HEMT prepared in this embodiment are similar to those in Embodiment 1, indicating that the device prepared according to this embodiment has stable performance.

The above embodiments are preferred implementations of the present disclosure, but the implementations of the present disclosure are not limited to these embodiments. Any other changes, modifications, substitutions, combinations, and simplifications made without departing from the spirit and principle of the present disclosure shall be equivalent replacement means and shall be included in the protection scope of the present disclosure.

What is claimed is:

1. A preparation method of a double-T-shaped gate based on double-layer passivation accurate etching, comprising:
sequentially growing two passivation layers on an epitaxial structure, wherein the two passivation layers comprise a bottom passivation layer and a top passivation layer;
performing a first exposure on the top passivation layer and etching the top passivation layer and the bottom passivation layer in a first exposure region from top to bottom to form a gate root region;
performing a second exposure on the top passivation layer and etching the top passivation layer in a second exposure region to form a lower gate cap region; and
performing a third exposure on the top passivation layer to form a top gate cap exposure region and performing a metal evaporation and removing a photoresist to form a double-T-shaped gate structure in the two passivation layers;
wherein the double-T-shaped gate comprises a gate root, a lower gate cap, and a top gate cap from bottom to top; a bottom of the gate root is in contact with the epitaxial structure, and a sidewall of the gate root is in contact with the bottom passivation layer; a bottom of the lower gate cap is in contact with an upper surface of the bottom passivation layer, and a sidewall of the lower gate cap is in contact with the top passivation layer; a bottom of the top gate cap is in contact with an upper surface of the top passivation layer, and a sidewall of the top gate cap is in contact with air.

2. The preparation method according to claim 1, comprising:
S1: growing the epitaxial structure on an epitaxial substrate and growing the two passivation layers on the epitaxial structure;
S2: coating the photoresist on the top passivation layer and performing the first exposure to expose the gate root region after development;
S3: performing a dry etching on the gate root region, wherein an etching depth of the dry etching is a thickness of the two passivation layers, and then removing the photoresist;
S4: spin-coating the photoresist on the top passivation layer again and performing the second exposure on the top passivation layer to expose the lower gate cap region after development;
S5: performing an accurate wet etching on the lower gate cap region, wherein an etching depth of the accurate wet etching is a thickness of the top passivation layer, and then removing the photoresist;
S6: spin-coating the photoresist on the top passivation layer again and performing the third exposure on the top passivation layer to expose the top gate cap region;
S7: performing the metal evaporation on the epitaxial wafer and then removing the photoresist to complete preparation of the double-T-shaped gate structure; and
S8: selecting an annealing atmosphere and an annealing temperature according to an electrode contact property to complete preparation of the double-T-shaped gate.

3. The preparation method according to claim 1, wherein a width of the top gate cap is greater than a width of the lower gate cap, and the width of the lower gate cap is greater than a width of the gate root.

4. The preparation method according to claim 1, wherein the top passivation layer is SiO₂, the bottom passivation layer is SiN, and the two passivation layers are grown using plasma-enhanced chemical vapor deposition (PECVD), low-pressure chemical vapor deposition (LPCVD), or atomic layer deposition (ALD).

5. The preparation method according to claim 2, wherein the dry etching in S3 is plasma etching, and an etching atmosphere is a fluorinated gas.

6. The preparation method according to claim 2, wherein a width of the top gate cap exposure region is greater than a width of a lower gate cap exposure region, and the width of the lower gate cap exposure region is greater than a width of a gate root exposure region.

7. The preparation method according to claim 2, wherein an etching solution used in the wet etching in S5 is a buffered oxide etch (BOE) solution.
